(19) United States
(12) Patent Application Publication
(10) Pub. No.: US 2007/0103871 A1
(43) Pub. Date: May 10, 2007

(54) HEAT DISSIPATION MODULE

(75) Inventor: Chih Chun Huang, Taipei City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: AMA PRECISION INC., Taipei City (TW)

(21) Appl. No.: 11/538,440

(22) Filed: Oct. 4, 2006

(30) Foreign Application Priority Data
Nov. 7, 2005 (TW) 94138935

(51) Int. Cl. H05K 7/20

(52) U.S. Cl. 361/704; 165/185

(57) ABSTRACT

A heat dissipation module is provided. The heat dissipation module comprises a fixing part and a plurality of heat dissipation fins. The heat dissipation fins are fastened unto the fixing part. Each heat dissipation fin has at least a bent portion. The bent portion connects to a first portion and a second portion. Furthermore, the first portion and the second portion are not located on the edge of the heat dissipation fin. Since the heat dissipation module uses fins having bent portions, a larger heat dissipation area is provided for achieving a better cooling effect.

### CROSS-REFERENCE TO RELATED APPLICATION

This application claims the priority benefit of Taiwan application serial no. 94138935, filed on Nov. 7, 2005. All disclosure of the Taiwan application is incorporated herein by reference.

### BACKGROUND OF THE INVENTION

1. Field of the Invention

The present invention relates to a heat dissipation module. More particularly, the present invention relates to a heat dissipation module with fins having at least a bent portion.

2. Description of the Related Art

With the continuous improvement in electronic technologies in recent years, the computing speed of the electronic devices used inside the computer has also been constantly increased. As the power rating of various electronic elements continues to increase, the heat associated with the operation also increases substantially. To prevent an electronic device from reaching an excessively high temperature that may slow down the device or even cause a temporary or permanent malfunction of the device, a cooling system with enough capacity to maintain a constant operating temperature must be deployed. The most common method of dissipating the heat produced by an electronic device is to mount a heat dissipation module over the electronic device. Thus, the heat produced by the electronic device as well as any heat accumulated around the device can be carried away through conduction or convection. In the following, the method of dissipating the heat generated by an electronic device is described in more detail with a diagram.

FIG. 1 is a perspective view of a conventional heat dissipation module. As shown in FIG. 1, the method of dissipating heat from an electronic device 130 is to mount a heat dissipation module 100 over it. The electronic device 130 may be a central processing unit (CPU) or other electronic component that generates lots of heat. The heat dissipation module 100 includes a heat sink 110 and a fan 120, wherein the heat sink 110 has a cooling plate 112 and a plurality of flat cooling fins 114 disposed in parallel to each other on the surface of the cooling plate 112. The bottom surface of the cooling plate 112 is attached to a surface of the electronic device 130. The electric fan 120 is disposed on top of the heat sink 110 with the air outlet facing down.

The heat produced by the electronic device 130 can conduct to the cooling fins 114 via the cooling plate 112. Then, the fan 120 forces air to blow down to the cooling fins 114 of the heat sink 110 and thus the hot air flows out via the sides so that a convection current with the air is established to carry the heat to the surrounding atmosphere, thereby lowering the temperature of the electronic device 130.

As shown in FIG. 1, to increase the heat dissipating capacity of a conventional heat dissipation module 100, the number of cooling fins 114 in the heat sink 110 must be increased so as to increase the heat dissipating area. However, the number of cooling fins 114 that can be put on the cooling plate 112 is restricted. Furthermore, the heat dissipating area that can be provided by a flat cooling fin 114 is quite limited. In addition, the density of cooling fins 114 will increase if more cooling fins 114 are added to the heat sink 110. The narrower separation between the cooling fins 114 will impede the flow of air through the fins 114 and reduce the heat dissipating capacity of the convective current.

### SUMMARY OF THE INVENTION

Accordingly, at least one objective of the present invention is to provide a heat dissipation module with a larger heat dissipating area for producing a better cooling effect.

To achieve this and other advantages and in accordance with the purpose of the invention, as embodied and broadly described herein, the invention provides a heat dissipation module. The heat dissipation module comprises a fixing part and a plurality of heat dissipation fins. The heat dissipation fins are fastened to the fixing part. Each heat dissipation fin has at least a bent portion. The bent portion connects to a first portion and a second portion. Furthermore, the first portion and the second portion are not located on the edge of the heat dissipation fin.

In one embodiment of the present invention, the first portion and the second portion can be a plane surface or a curve surface and the bent portion is formed by bending.

In one embodiment of the present invention, the bent portion can be a turning comer of the heat dissipation fins and the bent portion can have at least a slant surface.

In one embodiment of the present invention, the aforementioned fixing part includes a bottom block and a plurality of supporting tubes. The supporting tubes not only connect with the bottom block, but also pass through and fix to the heat dissipation fins. Furthermore, the supporting tubes may pass through the sides of the bottom block and extend upwards, for example.

In one embodiment of the present invention, the aforementioned heat dissipation fins may further include a plurality of first heat dissipation fins and a plurality of second heat dissipation fins. The first heat dissipation fins are stacked on top of each other with a gap maintained between each other and located on one side above the bottom block. Similarly, the second heat dissipation fins are stacked on top of each other with a gap maintained between each other and located the other side above the bottom block.

In one embodiment of the present invention, the first heat dissipation fins can be sequentially latched to each other. Similarly, the second dissipation fins can also be sequentially latched to each other.

In one embodiment of the present invention, the bent portion can connect to two plane surface or two curve surface. In addition, the bent portion can be one corner of the heat dissipation fin.

In one embodiment of the present invention, the heat dissipation module may further include a fan disposed above the bottom block and located between the first heat dissipation fins and the second heat dissipation fins. The fan can be an axial fan for driving air from the first heat dissipation fins toward the second heat dissipation fins.

In the present invention, the heat dissipation module uses heat dissipation fins having bent portions. Hence, the heat dissipation area is larger than the conventional flat dissipation fins. Thus, without increasing the number of heat dissipation fins and the fin density, a better cooling effect can be achieved.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 is a perspective view of a conventional heat dissipation module.

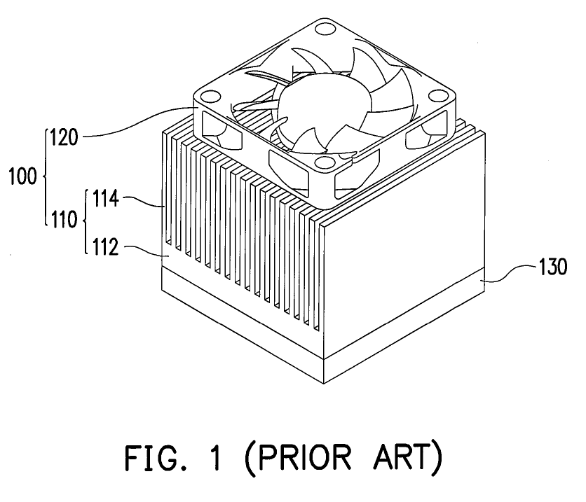

FIG. 2 is a perspective view of a heat dissipation module according to one embodiment of the present invention.

FIG. 3 is a side view of a heat dissipation module according to one embodiment of the present invention.

FIGS. 4A and 4B are respectively the perspective and side view of one heat dissipation fin according to the present invention.

FIG. 5 is a side view of a heat dissipation module according to another embodiment of the present invention.

FIG. 6 is another side view of the heat dissipation module shown in FIG. 5.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

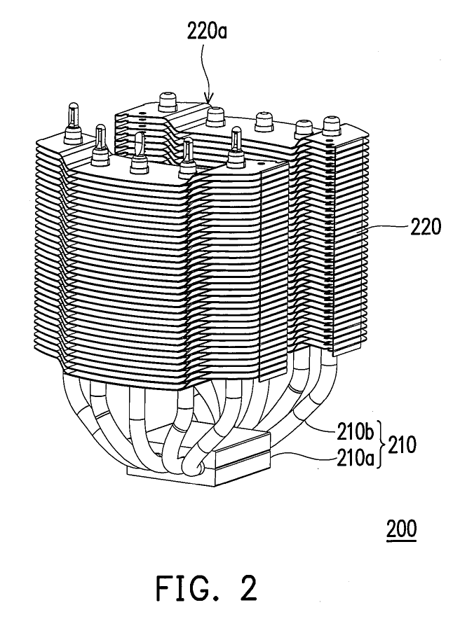

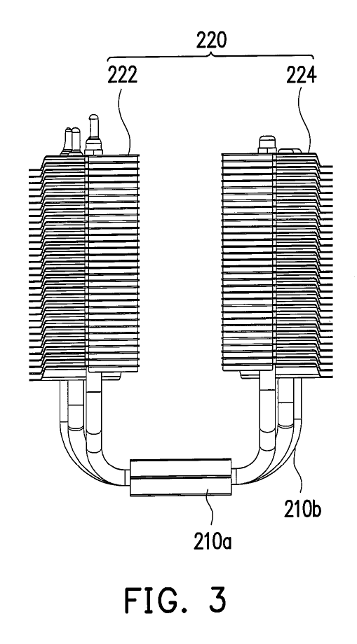

FIG. 2 is a perspective view of a heat dissipation module according to one embodiment of the present invention. FIG. 3 is a side view of a heat dissipation module according to one embodiment of the present invention. As shown in FIG. 2, the heat dissipation module 200 includes a fixing part 210 and a plurality of heat dissipation fins 220. The heat dissipation fins 220 are fastened to the fixing part 210. Each heat dissipation fin 220 has at least a bent portion 220a. The fixing part 210 may include a bottom block 210a and a plurality of supporting tubes 210b connected to the bottom block 210a. The supporting tubes pass through and clamp the heat dissipation fins 220 together. In the present embodiment, the heat dissipation fins 220 are fastened to the fixing part 210 by soldering to the supporting tubes 210b. Obviously, other methods (for example, a tight interference between the two) can be used to fasten the heat dissipation fins 220 to the fixing part 210. Hence, this should by no means limit the scope of the present invention.

In addition, as shown in FIG. 2, the supporting tubes 210b of the heat dissipation module 200 may pass through the sides of the bottom block 210a and extend upwardly to further pass through and fasten the heat dissipation fins 220. More specifically, the bottom block 210a may comprise two plate-like copper blocks stacked over each other. The two copper blocks together form a clamp that grips the mid-section of the supporting tubes 210.

As shown in FIG. 3, the heat dissipation fins 220 in the present, embodiment include a plurality of first heat dissipation fins 222 and a plurality of second heat dissipation fins 224. The first heat dissipation. fins 222 are stacked over each other with a gap maintained between them and disposed on one side of the bottom block 210a. Similarly, the second heat dissipation fins 224 are stacked over each other with a gap maintained between them and disposed on the other side of the bottom block 210a. In other words, the first heat dissipation fins 222 are disposed on one side above the bottom block 210a and the second heat dissipation fins 224 are disposed on the other side above the bottom block 210a. The first heat dissipation fins 222 and the second heat dissipation fins 224 are fixed by the supporting tubes 210b extending upwardly from the respective sides of the bottom block 210a and passing through them. Furthermore, the first heat dissipation fins 222 slide into the supporting tubes 210b and latch to each other in sequence. Similarly, the second heat dissipation fins 224 also slide into the supporting tubes 210b and latch to each other in sequence. The first heat dissipation fins 222 and the second heat dissipation fins 224 are soldered to the supporting tubes 210b. Alternatively, the heat dissipation fins 222 and 224 are passed into the supporting tubes 210b one after another and fixed in position through a tight tolerance. Obviously, the heat dissipation fins can be assembled together through some other means as the scope of the present invention is not limited as such.

It should be noted that the each heat dissipation fin in the heat dissipation module of the preferred embodiment of the present invention has at least a bent portion. The bent portion connects to a first portion and a second portion. Furthermore, the first portion and the second portion are not located on the edge of the heat dissipation fins. In the following, the structure of a typical heat dissipation fin is explained in more detail.

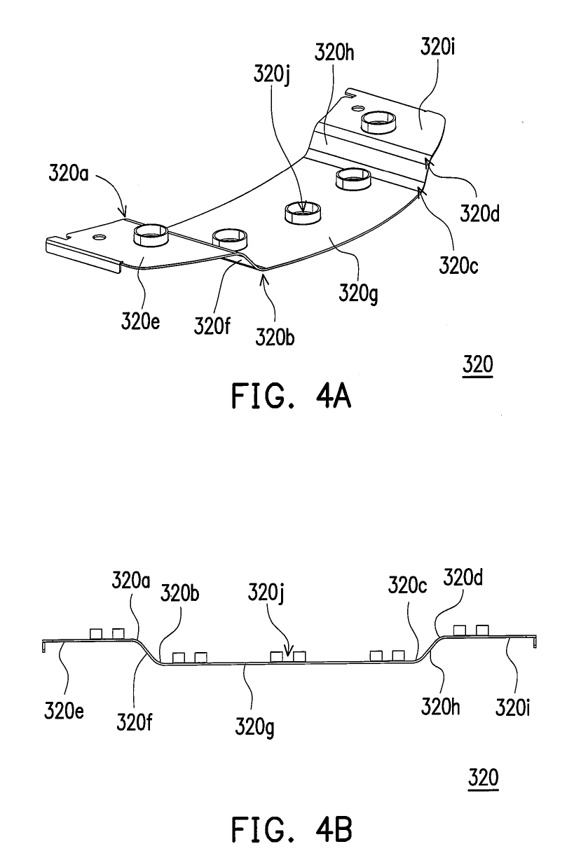

FIGS. 4A and 4B are respectively the perspective and side view of one heat dissipation fin according to the present invention. As shown in FIGS. 4A and 4B, the heat dissipation fin 320 includes four bent portions 320a, 320b, 320c, 320d and a first portion 320e, a second portion 320f, a third portion 320g, a fourth portion 320h, a fifth portion 320i. The bent portions 320a, 320b, 320c, 320d connect to the first portion 320e and the second portion 320f, the second portion 320f and the third portion 320g, the third portion 320g and the fourth portion 320h and the fourth portion 320h and the fifth portion 320i respectively. Furthermore, the bent portions 320a, 320b, 320c, 320d are not located on the edge of the heat dissipation fin 320. The first portion 320e, the second portion 320f, the third portion 320g, the fourth portion 320h and the fifth portion 320i are plane surfaces or curve surfaces with the bent portions 320a, 320b, 320c and 320d connecting them through bending. In other words, the heat dissipation fins 320 may be constructed using multiple sections of plane surfaces or curve surfaces with the bent portions 320a, 320b, 320c, 320d serving as a connection at the junctions between the plane surfaces or the curve surfaces. In addition, the bent portions 320a, 320b, 320c and 320d also provide some corner turning in the shape of the heat dissipation fin 320. Furthermore, each of these bent portions 320a, 320b, 320c and 320d can have at least a slant surface. By incorporating the bent portions 320a, 320b, 320c, 320d in the design of the heat dissipation fin 320, the surface area of the heat dissipation fin 320 increases significantly compared to the conventional flat fin.

In addition, the heat dissipation fin 320 can have a plurality of plug holes 320j formed therein that allows the supporting tubes 210b to penetrate and fix a number of heat dissipation fins 320 to the fixing part 210 of the heat dissipation module 200.

In the present invention, because the heat dissipation fins have a plurality of bent portions for joining plane surfaces or curved surfaces together, the total heat dissipation area is greater than the conventional heat sink with flat heat dissipation fins. Therefore, without increasing the number of fins or the fin density, the present invention can increase the heat dissipation area so that the heat exchange capacity of the heat dissipation module is increased. Ultimately, the heat dissipation module can provide a better cooling effect.

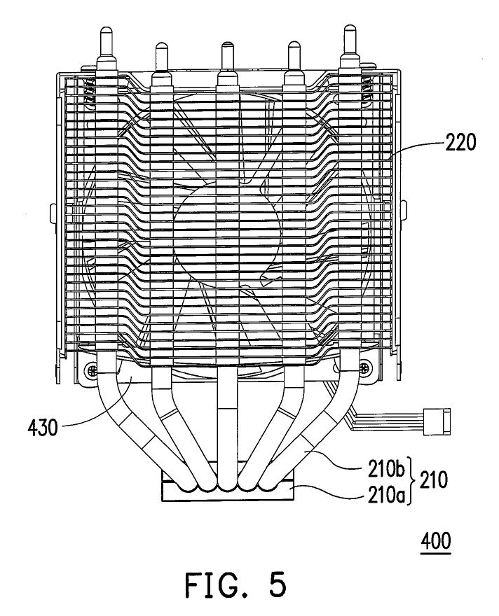

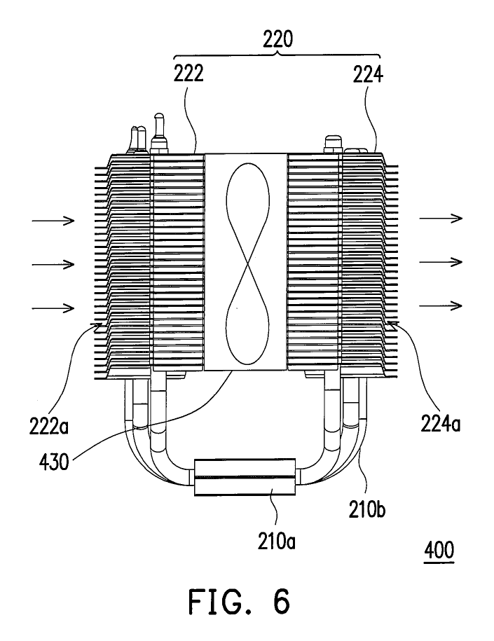

FIG. 5 is a side view of a heat dissipation module according to another embodiment of the present invention. FIG. 6 is another side view of the heat dissipation module shown in FIG. 5. As shown in FIGS. 5 and 6, the heat dissipation module 400 is similar to the heat dissipation module 200 in FIG. 2. The only difference is that an electric fan 430 is disposed in the heat dissipation module 400 above the bottom block 210a between the first heat dissipation fins 222 and the second heat dissipation fins 224. The fan 430 is an axial fan, for example, for driving air in the fin gaps 222a of the first heat dissipation fins 222 toward the fin gaps 224a of the second heat dissipation fins 224. In other words, the fan 430 can enhance the flow of air from the fin gaps 222a to the fin gaps 224a (the arrow in FIG. 6 shows the direction of movement of an air current). Therefore, the cooling capacity of the heat dissipation module 400 is further increased.

It should be noted that the heat dissipation fins have slant surfaces due to the presence of bent portions. These slant surfaces can be designed to match the shape of the fan blades and the air stream so that the cooling capacity is further increased.

In summary, the heat dissipation module of the present invention uses heat dissipation fins with bent portions so that the slant surfaces at the bents can increase the overall heat dissipation area. In other words, the heat dissipation module can provide a better cooling performance without increasing the number of heat dissipation fins and the fin density.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A heat dissipation module, comprising:
a fixing part; and
a plurality of heat dissipation fins fixed onto the fixing part, each heat dissipation fin having at least a bent portion, wherein the bent portion connects a first portion and a second portion and the first portion and the second portion are not located on an edge of the heat dissipation fins.

2. The heat dissipation module of claim 1, wherein the first portion and the second portion are plane surfaces or curve surfaces, and the bent portion is formed by bending.

3. The heat dissipation module of claim 1, wherein the bent portion in the heat dissipation fin is a turning corner and the bent portion has at least a slant surface.

4. The heat dissipation module of claim 1, wherein the fixing part comprises:
a bottom block; and
a plurality of supporting tubes connected to the bottom block and passing through and fixing to the heat dissipation fins.

5. The heat dissipation module of claim 4, wherein the supporting tubes pass through the sides of the bottom block and extend upwardly.

6. The heat dissipation module of claim 4, wherein the heat dissipation fins include:
a plurality of first heat dissipation fins stacked together with a gap between neighboring fins; and
a plurality of second heat dissipation fins stacked together with a gap between neighboring fins, wherein the first heat dissipation fins are disposed on one side above the bottom block and the second heat dissipation fins are disposed on the other side above the bottom block.

7. The heat dissipation module of claim 6, further including a fan disposed above the bottom block and between the first heat dissipation fins and the second heat dissipation fins.

8. The heat dissipation module of claim 7, wherein the fan includes an axial fan for driving air flowing through the first heat dissipation fins toward the second heat dissipation fins.

9. The heat dissipation module of claim 6, wherein the first heat dissipation fins latch to each other in sequence.

10. The heat dissipation module of claim 6, wherein the second heat dissipation fins latch to each other in sequence.
